(19) United States
(12) Patent Application Publication
(10) Pub. No.: US 2024/0008299 A1
(43) Pub. Date: Jan. 4, 2024

(54) LIGHT-EMITTING ELEMENT

(71) Applicant: SHARP KABUSHIKI KAISHA, Sakai City, Osaka (JP)

(72) Inventor: YOSHIHIRO UETA, Sakai City, Osaka (JP)

(21) Appl. No.: 18/037,749

(22) PCT Filed: Dec. 25, 2020
(86) PCT No.: PCT/JP2020/048609

§ 371 Date: May 18, 2023

(51) Int. Cl. H10K 50/115

(52) U.S. Cl. CPC H10K 50/115; H10K 59/1201

(57) ABSTRACT

A light-emitting element includes: a first electrode; a second electrode; and a quantum dot layer disposed between the first electrode and the second electrode. The quantum dot layer includes: a first quantum dot that is either an intrinsic quantum dot or an impurity quantum dot; and a second quantum dot disposed between the second electrode and the first quantum dot. The second quantum dot is either the intrinsic quantum dot or the impurity quantum dot other than the first quantum dot.

### TECHNICAL FIELD

The present disclosure relates to a light-emitting element.

### BACKGROUND ART

As to a light-emitting element including quantum dots, electrons and holes injected into the quantum dots are recombined so that the quantum dots emit light. The light-emitting element exhibits the highest light emission efficiency when the electrons and the holes to be injected into the quantum dots have the same density.

A quantum dot device described in Patent Document 1 includes light-emitting quantum dots and non-light-emitting quantum dots (paragraph [0007]). The light-emitting quantum dots and the non-light-emitting quantum dots may be found in the form of a mixture inside a quantum dot layer (paragraph [0053]). Alternatively, the light-emitting quantum dots and the non-light-emitting quantum dots may be respectively contained in a first quantum dot layer and a second quantum dot layer (paragraph [0089]). The light-emitting quantum dots have a core-shell structure, and the non-light-emitting quantum dots have a core structure without shells (paragraph) [0022]). As to the quantum dot device, the non-light-emitting quantum dots reduce mobility of the electrons, and function as a barrier moving from an electron transport layer to a quantum-dot layer (paragraph [0073]). The non-light-emitting quantum dots improve light emission efficiency of the quantum-dot device (paragraph [0106]).

### CITATION LIST

### Patent Literature

[Patent Document 1] United States Patent Application Publication No. 2019/0280232

### SUMMARY OF INVENTION

### Technical Problem

As described above, the light-emitting element including the quantum dots exhibits the highest light emission efficiency when the electrons and the holes to be injected into the quantum dots have the same density. However, as to a light-emitting element represented by the quantum dot device described in Patent Document 1, the electrons still tend to be excessively injected into the quantum dots. That is why the light-emitting element cannot exhibit the highest light emission efficiency.

The present disclosure is devised in view of this problem. An object of the present disclosure is to improve light emission efficiency of a display element including quantum dots.

### Solution to Problem

A light-emitting element according to an aspect of the present disclosure includes: a first electrode; a second electrode; and a quantum dot layer disposed between the first electrode and the second electrode. The quantum dot layer includes: a first quantum dot that is either an intrinsic quantum dot or an impurity quantum dot; and a second quantum dot disposed between the second electrode and the first quantum dot. The second quantum dot is either the intrinsic quantum dot or the impurity quantum dot other than the first quantum dot.

### BRIEF DESCRIPTION OF DRAWINGS

FIG. 1 is a plan view schematically illustrating a display device of a first embodiment.

FIG. 2 schematically illustrates cross-sectional views of pixels included in the display device of the first embodiment.

FIG. 3 is a cross-sectional view schematically illustrating a display device according to a first modification of the first embodiment.

FIG. 4 is an enlarged cross-sectional view schematically illustrating a quantum dot layer included in the display device of the first embodiment.

FIG. 5 is a schematic diagram illustrating a band structure in which a first electrode, a second electrode, a hole transport layer, an electron transport layer, a first quantum dot layer, and a second quantum dot layer included in the display device of the first embodiment are in an isolated state.

FIG. 6 is a schematic diagram illustrating a band structure in which the first quantum dot layer and the second quantum dot layer included in the display device of the first embodiment are in a junction/light-emission state.

FIG. 7 is an enlarged cross-sectional view schematically illustrating a quantum dot layer included in the display device according to a second modification of the first embodiment.

FIG. 8 is a schematic diagram illustrating a band structure in which an electron transport layer and a first quantum dot layer included in a display device of a second reference example are in an isolated state.

FIG. 9 is a schematic diagram illustrating a band structure in which an electron transport layer and a first quantum dot layer included in the display device of the second reference example are in a junction state.

FIG. 10 is a schematic diagram illustrating a band structure in which the electron transport layer and the second quantum dot layer included in the display device of the first embodiment are in an isolated state.

FIG. 11 is a schematic diagram illustrating a band structure in which the electron transport layer and the second quantum dot layer included in the display device of the first embodiment are in a junction state.

FIG. 12 is a schematic diagram illustrating a band structure in which the hole transport layer and the first quantum dot layer included in the display device of the first embodiment are in an isolated state.

FIG. 13 is a schematic diagram illustrating a band structure in which the hole transport layer and the first quantum dot layer included in the display device of the first embodiment are in a junction state.

FIG. 14 is a flowchart showing a method for producing second quantum dots included in the display device of the first embodiment.

FIG. 15 is a flowchart showing the method for producing the second quantum dots included in the display device of the first embodiment.

FIG. 16 is a graph showing a profile of temperatures of a reaction furnace in producing the second quantum dots to be included in the display device of the first embodiment.

FIG. 17 is a schematic diagram illustrating a band structure in which a first electrode, a second electrode, a hole transport layer, an electron transport layer, a first quantum dot layer, and a second quantum dot layer included in a display device of a second embodiment are in an isolated state.

FIG. 18 is a schematic diagram illustrating a band structure in which the hole transport layer and the first quantum dot layer included in the display device of the second embodiment are in a junction state.

FIG. 19 illustrates a band structure of the hole transport layer and the first quantum dot layer included in the display device of the second embodiment, and a schematic waveform representing a wave function of the electrons in the hole transport layer and the first quantum dot layer.

FIG. 20 illustrates a band structure of the hole transport layer and the first quantum dot layer included in the display device of the second embodiment, and a schematic waveform representing a wave function of the electrons in the hole transport layer and the first quantum dot layer.

FIG. 21 illustrates a band structure of the hole transport layer and the first quantum dot layer included in the display device of the second embodiment, and a schematic waveform representing a wave function of the electrons in the hole transport layer and the first quantum dot layer.

FIG. 22 schematically illustrates cross-sectional views of pixels included in a display device of the third embodiment.

FIG. 23 is a schematic diagram illustrating a band structure in which a first electrode, a second electrode, a hole transport layer, an electron transport layer, a first quantum dot layer, and a second quantum dot layer included in the display device of the third embodiment are in an isolated state.

FIG. 24 is a schematic diagram illustrating a band structure in which the first quantum dot layer and the second quantum dot layer included in the display device of the third embodiment are in a junction/light-emission state.

FIG. 25 is a schematic diagram illustrating a band structure in which a first electrode, a second electrode, a quantum dot layer, a hole transport layer, and an electron transport layer included in a light-emitting element of a first reference example are in an isolated state.

FIG. 26 is a schematic diagram illustrating a band structure in which the first electrode, the second electrode, the quantum dot layer, the hole transport layer, and the electron transport layer included in the light-emitting element of the first reference are in a junction state.

### DESCRIPTION OF EMBODIMENTS

Described below are embodiments of the present disclosure, with reference to the drawings. Note that like reference signs designate identical or corresponding components throughout the drawings. Such components will not be elaborated upon repeatedly.

### 1 Electron-Hole Balance in the Quantum Dot Layer

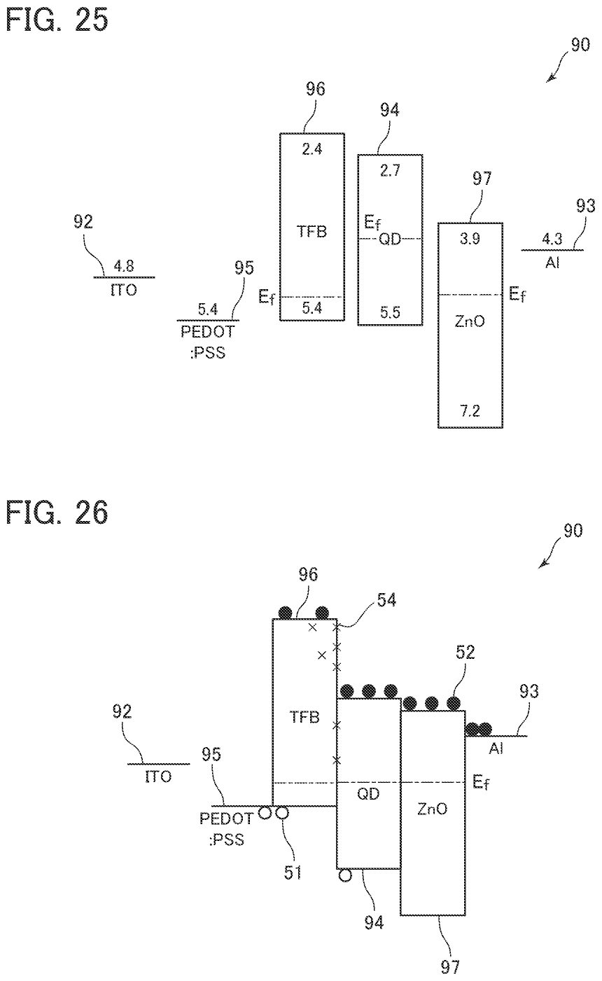

FIGS. 25 and 26 are schematic diagrams illustrating band structures of an anode 92, a cathode 93, a quantum dot layer 94, a hole injection layer 95, a hole transport layer 96, and an electron transport layer 97 included in a light-emitting element 90 of a first reference example. FIG. 25 illustrates a band structure in which the anode 92, the cathode 93, the quantum dot layer 94, the hole injection layer 95, the hole transport layer 96, and the electron transport layer 97 are isolated from one another in an isolated state. FIG. 26 illustrates a band structure in which the anode 92, the cathode 93, the quantum dot layer 94, the hole injection layer 95, the hole transport layer 96, and the electron transport layer 97 are joined together in a junction state.

Each of FIGS. 25 and 26 illustrates levels of the anode 92, the cathode 93, and the hole injection layer 95, and band gaps of the quantum dot layer 94, the hole transport layer 96, and the electron transport layer 97. Moreover, FIG. 26 illustrates holes 51, electrons 52, and defects 54.

The anode 92 is made of indium tin oxide (ITO). The cathode 93 is made of Al. The quantum dot layer 94 is made of quantum dots (QDs). The hole injection layer 95 is made of poly(3,4-ethylenedioxythiophene): poly(4-styrenesulfonic acid) (PEDOT:P SS). The hole transport layer 96 is made of poly(2,7-(9,9-di-n-octylfluorene)-(1,4-phenylene-((4-sec-butylphenyl)imino)-1,4-phenylene (TFB). The electron transport layer 97 is made of ZnO.

In the isolated state, the anode 92 has a level of 4.8 eV. Moreover, the cathode 93 has a level of 4.3 eV. In addition, the hole injection layer 95 has a level of 5.4 eV. Furthermore, the quantum dot layer 94 has a conduction band minimum (CBM) of 2.7 eV and a valence band maximum (VBM) of 5.5 eV, and has a Fermi level E_{f} near a middle between the CBM and VBM inside the band gap. The hole transport layer 96 has a CBM of 2.4 eV and a VBM of 5.4 eV, and has a Fermi level E_{f} near the VBM inside the band gap. The electron transport layer 97 has a CBM of 3.9 eV and a VBM of 7.2 eV, and has a Fermi level E_{f} near the CBM inside the band gap. In the junction state, the bands of the quantum dot layer 94, the hole transport layer 96, and the electron transport layer 97 change so that the Fermi levels E_{f} match.

Note that a value indicating energy referred to in the illustration of the schematic diagram of the band structure is an approximate absolute value of a difference between the referred energy and the vacuum level. In addition, when the band is in a deep position, it means that the absolute value of the difference between the vacuum level and the position of the band is large. On the other hand, when the band is in a shallow position, it means that the absolute value of the difference between the vacuum level and the position of the band is small.

When the light-emitting element 90 of the first reference example operates, the electrons 52 to be injected into the quantum dot layer 94 are more likely to be excessive with respect to holes 51 to be injected into the quantum dot layer 94. Hence, the light emitting element 90 has probably only low external quantum efficiency (EQE). Moreover, the hole transport layer 96 made of an organic material is more prone to deterioration due to the excessive electrons 52. For example, the defects 54 are probably formed on the hole transport layer 96.

Embodiments described below are provided to solve these problems.

### 2 First Embodiment

### 2.1 Planar Configuration of Display Device

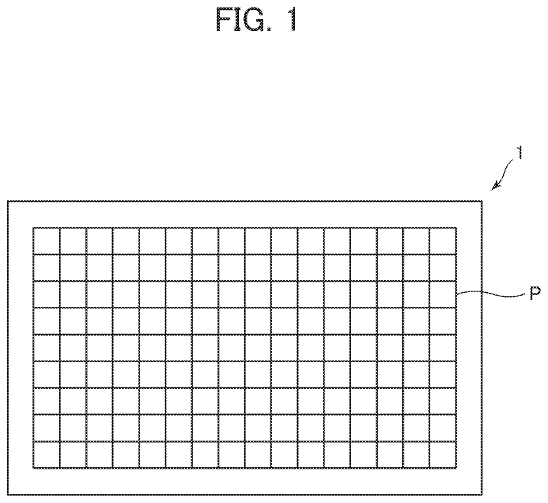

FIG. 1 is a plan view schematically illustrating a display device 1 of a first embodiment.

The display device 1 includes quantum-dot light-emitting diodes (QLEDs). In the present disclosure, the quantum dots have a maximum width of 1 nm or more and 100 nm or less. The quantum dots have any given shape as long as the quantum dots have the maximum width. Hence, the quantum dots may have a cross-section shaped other than a circular cross-sectional shape, or may have a three-dimensional shape other than a spherical three-dimensional shape. For example, the quantum dots may have a cross-section shaped into a polygon. Alternately, the quantum dots may have three-dimensional shapes such as rods or branches, or may have a three-dimensional shape such that the surface of the quantum dots has asperities. The quantum dots may have a shape obtained in combination of these shapes.

As illustrated in FIG. 1, the display device 1 includes a plurality of pixels P.

The plurality of pixels P are arranged in a matrix. The plurality of pixels P may be arranged not in a matrix.

### 2.2 Cross-Sectional Structure of Pixel

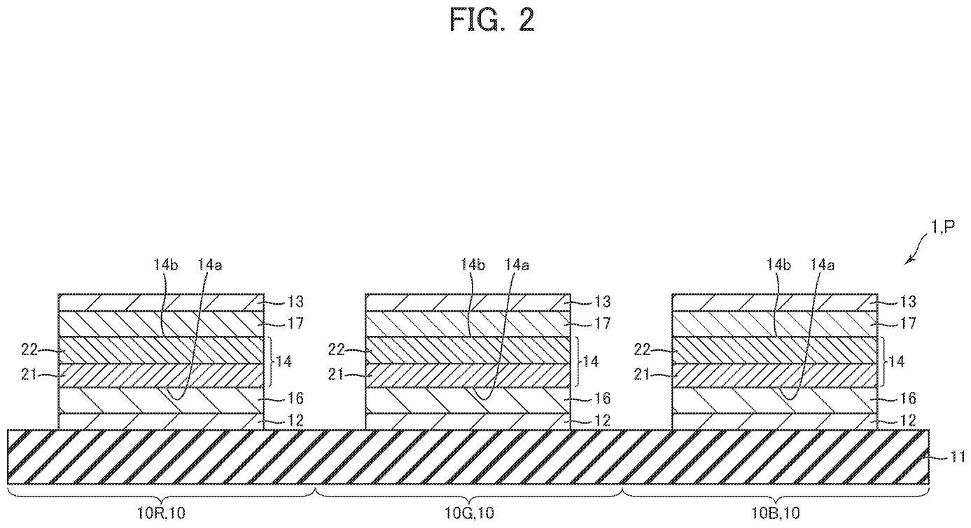

FIG. 2 schematically illustrates cross-sectional views of pixels P included in the display device 1 of the first embodiment.

As illustrated in FIG. 2, the display device 1 includes light-emitting elements 10R, 10G, and 10B.

The light-emitting element 10R, the light-emitting element 10G, and the light-emitting element 10B respectively emit a red light, a green light, and a blue light. Each of the light-emitting elements 10R, 10G, and 10B may emit light in a color other than red, green, and blue.

As illustrated in FIG. 2, each of the light-emitting elements 10; that is, the light-emitting elements 10R, 10G, and 10B, includes: a substrate 11; a first electrode 12; a second electrode 13; a quantum dot layer 14; a hole transport layer 16; and an electron transport layer 17. The first electrode 12 is an anode. The second electrode 13 is a cathode.

In the display device 1, the substrate 11 is continuously disposed across the light emitting elements 10R, 10G, and 10B. Moreover, three quantum dot layers 14 separated from one another are disposed to the three respective light-emitting elements 10R, 10G, and 10B. Furthermore, three hole transport layers 16 separated from one another are disposed to the three respective light-emitting elements 10R, 10G, and 10B. In addition, three electron transport layers 17 separated from one another are disposed to the three respective light-emitting elements 10R, 10G, and 10B. A continuous hole transport layer 16 may be disposed across the light-emitting elements 10G, and 10B. A continuous electron transport layer 17 may be disposed across the three light-emitting elements 10R, 10G, and 10B.

The substrate 11 is an array substrate. Desirably, the substrate 11 is a thin-film transistor (TFT) array substrate. The first electrode 12, the second electrode 13, the quantum dot layer 14, the hole transport layer 16, and the electron transport layer 17 are stacked on top of another above the substrate 11.

The quantum dot layer 14, the hole transport layer 16, and the electron transport layer 17 are disposed between the first electrode 12 and the second electrode 13. The hole transport layer 16 is disposed between the first electrode 12 and the quantum dot layer 14. The electron transport layer 17 is disposed between the second electrode 13 and the quantum dot layer 14.

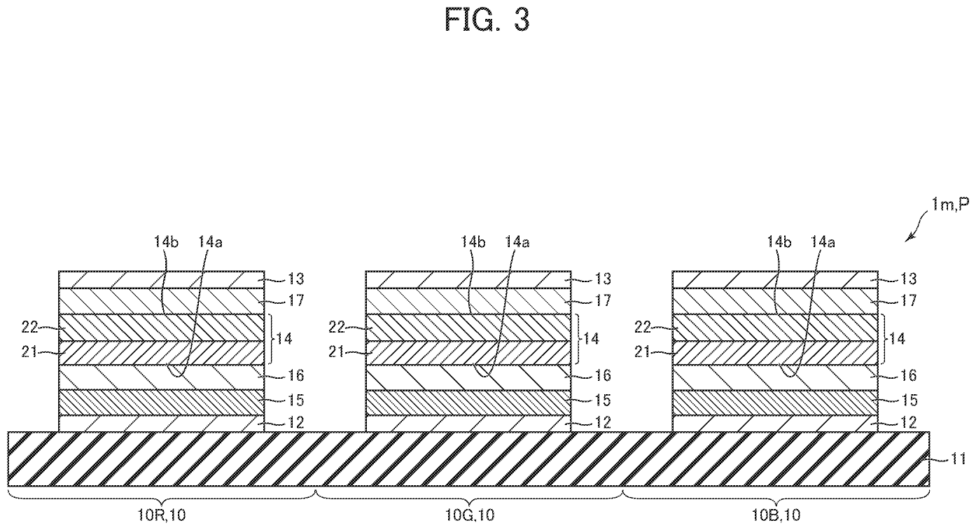

FIG. 3 is a cross-sectional view schematically illustrating a display device lm according to a first modification of the first embodiment.

As illustrated in FIG. 3, each light emitting element 10 may include a hole injection layer 15 disposed between the first electrode 12 and the hole transport layer 16.

In addition, each light-emitting element 10 may include a passivation layer disposed between the quantum dot layer 14 and the hole transport layer 16. The passivation layer is made of, for example, Al₂O₃.

Each light-emitting element 10 may include an insulating layer disposed between the quantum dot layer 14 and the electron transport layer 17. This insulating layer can inactivate defects found on a main surface of the quantum dot layer 14 toward the electron transport layer 17. Moreover, the insulating layer can inactivate defects found on a main surface of the electron transport layer 17 toward the quantum dot layer 14. The insulating layer is made of, for example, Al₂O₃. The insulating layer has a thickness that does not block tunneling of the electrons 52. The thickness is, for example, 5 nm or less.

### 2.3 Light Emission from the Light-Emitting Device

As illustrated in FIG. 2, the first electrode 12 is in contact with the quantum dot layer 14 through the hole transport layer 16. The first electrode 12 supplies the holes 51 to the hole transport layer 16. The hole transport layer 16 transports the supplied holes 51 to the quantum dot layer 14, and injects the transported holes 51 into the quantum dot layer 14. Thus, the holes 51 can be injected from the first electrode 12 through the hole transport layer 16 into the quantum dot layer 14.

If each light-emitting element 10 includes the hole injection layer 15, the first electrode 12 is in contact with the quantum dot layer 14 through the hole injection layer 15 and the hole transport layer 16. The first electrode 12 supplies the holes 51 to the hole injection layer 15. The hole injection layer 15 injects the supplied holes 51 into the hole transport layer 16. The hole transport layer 16 transports the injected holes 51 to the quantum dot layer 14, and injects the transported holes 51 into the quantum dot layer 14. Thus, the holes 51 can be injected from the first electrode 12 through the hole injection layer 15 and the hole transport layer 16 into the quantum dot layer 14.

The second electrode 13 is in contact with the quantum dot layer 14 through the electron transport layer 17. The second electrode 13 supplies the electrons 52 to the electron transport layer 17. The electron transport layer 17 transports the supplied electrons 52 to the quantum dot layer 14, and injects the transported electrons 52 into the quantum dot layer 14. Thus, the electrons 52 can be injected from the second electrode 13 through the electron transport layer 17 into the quantum dot layer 14.

When a drive voltage is applied between the first electrode 12 and the second electrode 13, the holes 51 are injected from the first electrode 12 into the quantum dot layer 14. Moreover, the electrons 52 are injected from the second electrode 13 into the quantum dot layer 14. Hence, the holes 51 and the electrons 52 recombine in the quantum dot layer 14. Accordingly, the quantum dot layer 14 emits light.

### 2.4 Conventional Structure and Inverted Structure

The display device 1 has a non-inverted structure. Thus, as illustrated in FIG. 2, the first electrode 12, the hole transport layer 16, the quantum dot layer 14, the electron transport layer 17, and the second electrode 13 are stacked on top of another in the stated order above the substrate 11.

The display device 1 may have an inverted structure. If the display device 1 has an inverted structure, the first electrode 12, the hole transport layer 16, the quantum dot layer 14, the electron transport layer 17, and the second electrode 13 are stacked on top of another in the inverted order of the stated order above the substrate 11.

### 2.5 Top Emission Type and Bottom Emission Type

The display device 1 is a top-emission display device. Hence, the first electrode 12 is reflective to light. Moreover, light emitted by the quantum dot layer 14 is released toward the opposite side of the substrate 11. If the display device 1 has an inverted structure, the second electrode 13 is reflective to light.

The display device 1 may also be a bottom-emission display device. In such a case, the first electrode 12 is transparent to light. Furthermore, light emitted by the quantum dot layer 14 is released toward the substrate 11. If the display device 1 has an inverted structure, the second electrode 13 is transparent to light.

### 2.6 Cross-Sectional Structure of Quantum Dot Layer

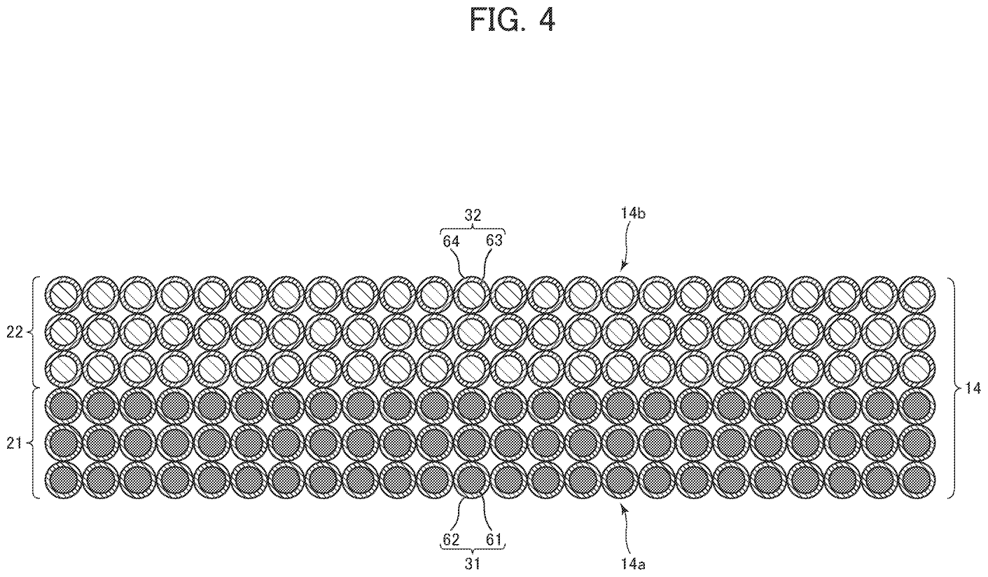

FIG. 4 is an enlarged cross-sectional view schematically illustrating the quantum dot layer 14 included in the display device 1 of the first embodiment.

As illustrated in FIGS. 2 and 4, the quantum dot layer 14 includes the first quantum dot layer 21 and the second quantum dot layer 22.

The first quantum dot layer 21 and the second quantum dot layer 22 are stacked on top of each other. The quantum dot layer 14 has: a first end portion 14a toward the first electrode 12; and a second end portion 14b toward the second electrode 13.

As illustrated in FIG. 4, the first quantum dot layer 21 includes a plurality of first quantum dots 31. Moreover, the second quantum dot layer 22 includes a plurality of second quantum dots 32.

The second quantum dot layer 22 is disposed between the second electrode 13 and the first quantum dot layer 21.

The second quantum dot layer 22 is disposed between the second electrode 13 and the first quantum dot layer 21. Hence, all of the plurality of second quantum dots 32 are disposed between the second electrode 13 and some of the plurality of first quantum dots 31. Moreover, the plurality of first quantum dots 31 and the plurality of second quantum dots 32 are disposed such that, at the first end portion 14a, a rate of the number of quantum dots that belong to the plurality of first quantum dots 31 to the sum of the number of the quantum dots that belong to the plurality of first quantum dots 31 and the number of quantum dots that belong to the plurality of second quantum dots 32 is the highest rate of 100%, and, at the second end portion 14b, a rate of the number of quantum dots that belong to the plurality of second quantum dots 32 to the sum of the number of quantum dots that belong to the plurality of first quantum dots 31 and the number of the quantum dots that belong to the plurality of second quantum dots 32 is the highest rate of 100%.

### 2.7 Conductive Type of Quantum Dots

In the display device 1 of the first embodiment, the plurality of first quantum dots 31 are a plurality of intrinsic quantum dots. Moreover, the plurality of second quantum dots 32 are a plurality of impurity quantum dots. The impurity quantum dots are n-type impurity quantum dots. The intrinsic quantum dots, not including dopant impurities, contain an intrinsic material not doped with impurities. The impurity quantum dots include dopant impurities, and contain an impurity material doped with impurities. The impurity material is an n-type impurity material.

### 2.8 Band Structure of Quantum Dot Layer

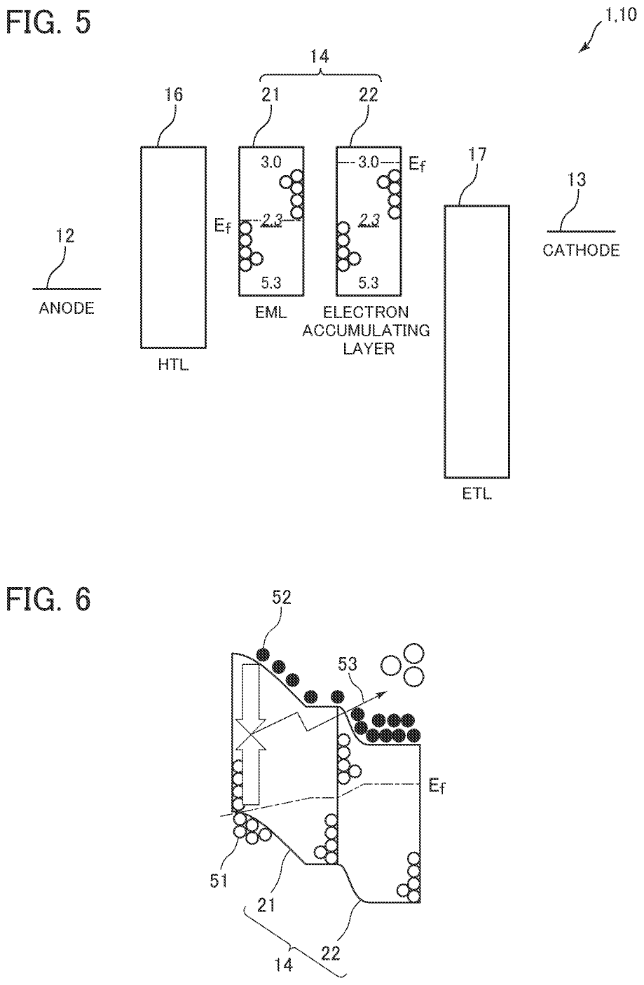

FIG. 5 is a schematic diagram illustrating a band structure of the first electrode 12, the second electrode 13, the hole transport layer (HTL) 16, the electron transport layer (ETL) 17, the first quantum dot layer 21 serving as a light-emitting layer (EML), and the second quantum dot layer 22 serving as an electron accumulating layer, all of which are included in the display device 1 of the first embodiment. FIG. 5 illustrates a band structure in which the first electrode 12, the second electrode 13, the hole transport layer 16, the electron transport layer 17, the first quantum dot layer 21, and the second quantum dot layer 22 are isolated from one another in an isolated state.

FIG. 5 illustrates levels of the first electrode 12 and the second electrode 13, and band gaps of the hole transport layer 16, the electron transport layer 17, the first quantum dot layer 21, and the second quantum dot layer 22.

As illustrated in FIG. 5, in the isolated state, the first quantum dot layer 21 and the second quantum dot layer 22 have, for example, a CBM of 3.0 eV, a VBM of 5.3 eV, and a band gap of 2.3 eV. The first quantum dot layer 21, which contains an intrinsic semiconductor, has a Fermi level E_{f} near a middle between the CBM and VBM inside the band gap. The second quantum dot layer 22, which contains an n-type impurity semiconductor, has a Fermi level E_{f} near the CBM inside the band gap.

FIG. 6 is a schematic diagram illustrating a band structure of the first quantum dot layer 21 and the second quantum dot layer 22 included in the display device 1 of the first embodiment. FIG. 6 illustrates a band structure in a junction/light-emission state in which the first quantum dot layer 21 and the second quantum dot layer 22 join together and the first quantum dot layer 21 emits light 53.

FIG. 6 illustrates the band gaps of the first quantum dot layer 21 and the second quantum dot layer 22. Moreover, FIG. 6 illustrates the holes 51, the electrons 52, and the light 53.

As illustrated in FIG. 6, in the junction/light-emission state, the bands of the first quantum dot layer 21 and the second quantum dot layer 22 curve, so that the Fermi level E_{f} of the first quantum dot layer 21 and the Fermi level E_{f} of the second quantum dot layer 22 match. Hence, a deep potential is formed in the second quantum dot layer 22 to accumulate the electrons 52.

The n-type impurity semiconductor contained in the second quantum dot layer 22 has a density of state of 10¹⁹ cm⁻³ or more. On the other hand, the electrons 52, which are injected into the n-type impurity semiconductor in the junction/light-emission state, have a highest density of only about of 10¹⁶ cm⁻³. Hence, it is unlikely that electrons 52 injected into the second quantum dot layer 22 overflow the second quantum dot layer 22.

Thus, the second quantum dot layer 22 serves as an electron accumulating layer that effectively accumulates the electrons 52.

When the first quantum dot layer 21 and the second quantum dot layer 22 join, the charges moves so that the Fermi levels E_{f} of the both layers match and a depletion layer is formed. The depletion layer serves as an electron barrier that keeps the electrons 52 from moving from the second electrode 13 toward the first electrode 12. When an external power source is connected between the first electrode 12 and the second electrode 13 included in the light-emitting element 10 while the first and second quantum dot layers 21 and 22 join, the Fermi level E_{f} is inclined by the electric field as illustrated in FIG. 6. However, the second quantum dot layer 22 can effectively confine the electrons 52, injected from the electron transport layer 17, with the electron barrier.

Moreover, when the first quantum dot layer 21 and the second quantum dot layer 22 join, the junction serves as a hole barrier that keeps the holes 51 from moving from the first electrode 12 toward the second electrode 13. Hence, the first quantum dot layer 21 can effectively confine the holes 51 injected from the hole transport layer 16.

The holes 51 have an effective mass approximately ten times an effective mass of the electron 52. Hence, with the hole barrier, the holes 51 injected into the first quantum dot layer 21 are kept from reaching the second quantum dot layer 22. Thus, in the second quantum dot layer 22, the electrons 52 are found; however, the holes 51 are less likely to be found. As a result, in the second quantum dot layer 22, the holes 51 and the electrons 52 are unlikely to recombine, and the second quantum dot layer 22 is kept from emitting the light 53.

A difference between the CBM of the first quantum dot layer 21 containing an intrinsic semiconductor and the CBM of the second quantum dot layer 22 containing an n-type impurity semiconductor is smaller than a difference between the CBM of a p-type semiconductor and the CBM of an n-type semiconductor joined to the p-type semiconductor with p-n junction. Moreover, when a drive voltage is applied between the first electrode 12 and the second electrode 13, the current flowing through the junction between the first quantum dot layer 21 and the second quantum dot layer 22 is a forward current. Hence, in the display device 1 of the first embodiment, the electrons 52 can be injected from the second quantum dot layer 22 to the first quantum dot layer 21 without significantly increasing the drive voltage.

When the drive voltage is applied between the first electrode 12 and the second electrode 13, and an external electric field is applied to the quantum dot layer 14, to the hole transport layer 16, and to the electron transport layer 17, the holes 51 are injected into the first quantum dot layer 21. Moreover, the electrons 52 are injected into the second quantum dot layer 22. Some of the electrons injected into the second quantum dot layer 22 are accumulated in the second quantum dot layer 22. The rest of the electrons injected into the second quantum dot layer 22 are injected into the first quantum dot layer 21. The first quantum dot layer 21 allows the injected holes 51 and electrons 52 to recombine, and emits the light 53. Hence, the first quantum dot layer 21 serves as a light-emitting to emit the light 53.

Typically, in an impurity semiconductor, such phenomena as scattering of charges by impurities and trapping of charges by the impurity levels inhibit radiative recombination of the holes 51 and the electrons 52. Depending on the concentration of the doped impurities, an impurity level has a width inside the band gap and stretches toward a lower energy. In the display device 1 of the first embodiment, the plurality of first quantum dots 31 including an intrinsic material cause radiative recombination of the hole 51 and the electron 52. However, the plurality of second quantum dots 32 containing an impurity material are less likely to cause the radiative recombination of the holes 51 and electrons 52. That is why the radiative recombination of the holes 51 and the electrons 52 is less likely to be inhibited because of the scattering of charges by impurities and the trapping of charges by impurity levels. Such a feature makes it possible to increase the chance of the radiative recombination between the valence band and the conduction band.

In the display device 1 of the first embodiment, a deep potential and an electron barrier are formed between the second electrode 13 and the plurality of first quantum dots 31 emitting the light 53. The deep potential accumulates the electrons 52, and the electron barrier keeps the electrons 52 from moving from the second electrode 13 toward the first electrode 12. Such a feature makes it possible to reduce the injection of the electrons 52 into the first quantum dots 31 emitting the light 53. Hence, electron-hole balance can be improved between the hole 51 and the electrons 52 to be injected into the plurality of first quantum dots 31 emitting the light 53. Thus, the holes 51 and the electron 52 can be kept from non-radiatively recombining, and the electron 52 can be less likely to be lost. As a result, each of the light-emitting elements 10 can improve light emission efficiency.

Moreover, in the display device 1 of the first embodiment, a deep potential and an electron barrier are formed over the entire surface of the quantum dot layer 14. Hence, over the entire surface of the quantum dot layer 14, electron-hole balance can be improved between the holes 51 and the electrons 52 to be injected into the plurality of first quantum dots 31 emitting the light 53.

Furthermore, in the display device 1 of the first embodiment, the number of quantum dots that belong to the plurality of first quantum dots 31 increases at the first end portion 14a of the quantum dot layer 14, and the number of quantum dots that belong to the plurality of second quantum dots 32 increases at the second end portion 14b of the quantum dot layer 14. Such a feature can improve the electron-hole balance between the holes 51 and the electrons 52 at least at the first end portion 14a and the second end portion 14b of the quantum dot layer 14.

When the electrons 52 overflow the first quantum dot layer 21 into the hole transport layer 16, the hole transport layer 16 deforms as seen in anodization. Hence, defects are formed in the hole transport layer 16. The defects decrease the reliability of each light-emitting element 10. For example, as time passes, hole transport capability of the hole transport layer 16 decreases. Thus, as time elapses, the decreasing hole transport capability inevitably causes a rise of the driving voltage to be applied between the first electrode 12 and the second electrode 13 when each light-emitting element 10 emits the light 53. In addition, as time elapses, the external quantum efficiency of each light-emitting element 10 decreases. If each light-emitting element includes the hole injection layer 15, the same problems could occur also to the hole injection layer 15.

However, in the display device 1 of the first embodiment, a deep potential and an electron barrier are formed between the second electrode 13 and the plurality of first quantum dots 31 emitting the light 53. The deep potential accumulates the electrons 52, and the electron barrier keeps the electrons 52 from moving from the second electrode 13 toward the first electrode 12. The deep potential and the electron barrier can keep the electrons 52 from overflowing the first quantum dot layer 21 into the hole transport layer 16. If each light-emitting element 10 includes the hole injection layer 15, the deep potential and the electron barrier can keep the electrons 52 from overflowing the first quantum dot layer 21 also into the hole injection layer 15. As a result, each light-emitting element 10 can improve reliability.

### 2.9 Another Example of Quantum Dot Layer

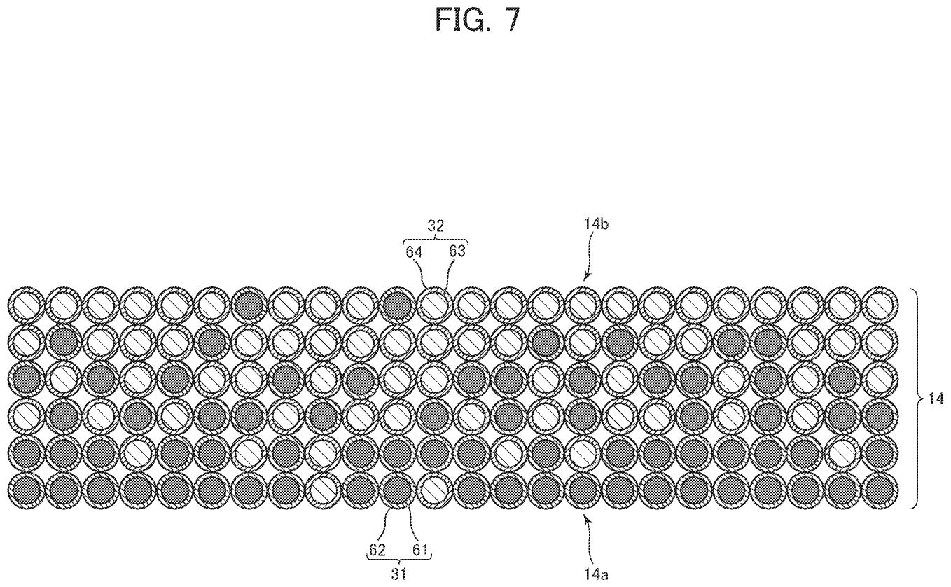

FIG. 7 is an enlarged cross-sectional view schematically illustrating the quantum dot layer 14 included in the display device according to a second modification of the first embodiment.

As illustrated in FIG. 7, in the display device according to the second modification of the first embodiment, the plurality of first quantum dots 31 and the plurality of second quantum dots 32 are mixed together. In this case, at least some of the plurality of second quantum dots 32 are disposed between the second electrode 13 and first quantum dots 31 included in the plurality of first quantum dots 31. Moreover, the plurality of first quantum dots 31 and the plurality of second quantum dots 32 are disposed such that, at the first end portion 14a, a rate of the number of quantum dots that belong to the plurality of first quantum dots 31 to the sum of the number of the quantum dots that belong to the plurality of first quantum dots 31 and the number of quantum dots that belong to the plurality of second quantum dots 32 is the highest rate, and, at the second end portion 14b, a rate of the number of quantum dots that belong to the plurality of second quantum dots 32 to the sum of the number of quantum dots that belong to the plurality of first quantum dots 31 and the number of the quantum dots that belong to the plurality of second quantum dots 32 is the highest rate.

The quantum dot layer 14 may include an insulating layer disposed between the first quantum dot layer 21 and the second quantum dot layer 22. This insulating layer can inactivate defects found on a main surface of the first quantum dot layer 21 toward the second quantum dot layer 22. Moreover, the insulating layer can inactivate defects found on a main surface of the second quantum dot layer 22 toward the first quantum dot layer 21. The insulating layer is made of, for example, Al₂O₃. The insulating layer has a thickness that does not block tunneling of the electrons 52. The thickness is, for example, 5 nm or less.

Inside the quantum dot layer 14, the first quantum dots 31 and the second quantum dots 32 do not have to be separated into layers. Moreover, the first quantum dots 31 and the second quantum dots 32 do not have to be separately disposed from one another. For example, inside the quantum dot layer 14, the first quantum dots 31 and the second quantum dots 32 may be uniformly distributed. The reason is described below.

The electrons inside the quantum dot layer 14 move from the second electrode 13 toward the first electrode 12. Even if the first quantum dots 31 and the second quantum dots 32 are uniformly distributed, if a movement path of the moving electrons includes at least one section in which the electrons move from a second quantum dot 32 to a first quantum dot 31, as to the behavior of the electrons, the same advantageous effect as that obtained by the first quantum dot layer 21 and the second quantum dot layer 22 can be obtained in the section. Hence, as to the behavior of the electrons, the same advantageous effect as that obtained by the first quantum dot layer 21 and the second quantum dot layer 22 can be obtained even though the effect is small.

The holes inside the quantum dot layer 14 move from the first electrode 12 toward the second electrode 13. Even if the first quantum dots 31 and the second quantum dots 32 are uniformly distributed, if a movement path of the moving holes includes at least one section in which the holes move from a first quantum dot 31 to a second quantum dot 32, as to the behavior of the holes, the same advantageous effect as that obtained by the first quantum dot layer 21 and the second quantum dot layer 22 can be obtained in the section. Hence, the same advantageous effect as that obtained by the first quantum dot layer 21 and the second quantum dot layer 22 can be obtained even though the effect is small.

Moreover, even if the first quantum dots 31 and the second quantum dots 32 are uniformly distributed, if a movement path of the electrons and a movement path of the holes include at least one section in which the holes and the electrons move from one of a pair of a common first quantum dot 31 and a common second quantum dot 32 to the other, as to the behavior of the holes and the electrons, the same advantageous effect as that obtained by the first quantum dot layer 21 and the second quantum dot layer 22 can be obtained in the section. Hence, the same advantageous effect as that obtained by the first quantum dot layer 21 and the second quantum dot layer 22 can be obtained even though the effect is small.

### 2.10 Materials of Quantum Dot Layer

The first quantum dots 31 included in the first quantum dot layer 21 typically contain a semiconductor. The semiconductor as used herein does not mean a semiconductor in distinction between a conductor, a semiconductor, and an insulator on the basis of resistivity. The semiconductor means a material having a certain band gap and capable of emitting light, and includes at least the materials described below. The first quantum dots 31 included in the light-emitting elements 10R, 10G, and 10B emit a red light, a green light, and a blue light.

The second quantum dots 32 included in the second quantum dot layer 22 contain an n-type impurity semiconductor. The n-type impurity semiconductor is formed of a semiconductor of the same type as the n-type impurity semiconductor. The semiconductor is doped with impurities. In doping the semiconductor with the impurities, the impurities are added to the semiconductor when, for example, the second quantum dots 32 are produced.

The semiconductor includes at least one selected from the group consisting of, for example, a group II-VI compound, a group III-V compound, a chalcogenide, and a perovskite compound. Note that the group II-VI compound means a compound containing a group II element and a group VI element, and the group III-V compound means a compound containing a group III element and a group V element. Moreover, the group II element may include a group 2 element and a group 12 element, the group III element may include a group 3 element and a group 13 element, the group V element may include a group 5 element and a group 15 element, and the group VI element may include a group 6 element and a group 16 element.

The group II-VI compound includes at least one selected from the group consisting of, for example, MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe. The impurities to be doped into the group II-VI compound include at least one selected from the group consisting of, for example, a group III element and Mn. The group III element includes at least one selected from the group consisting of, for example, Al, Ga, and In.

The group III-V compound includes at least one selected from the group consisting of, for example, GaAs, GaP, InN, InAs, InP and InSb. The impurities doped into the group III-V compound include, for example, a group IV element. The group IV element includes at least one selected from the group consisting of, for example, Si and Ge. Note that the group IV element may include a group 4 element and a group 14 element.

The chalcogenide is a compound containing a VI A (16) group element, and includes, for example, CdS or CdSe. The chalcogenide may contain a mixed crystal of these elements. The impurities doped into the chalcogenide include, for example, halogen. Halogen includes at least one selected from the group consisting of, for example, Cl and I.

The perovskite compound has a composition represented by, for example, a general formula CsPbX₃. The constituent element X includes at least one selected from the group consisting of, for example, Cl, Br, and I. The impurities doped into the perovskite compound include at least one selected from the group consisting of, for example, a group V element and La. The group V element includes, for example, P. Doping a perovskite compound with impurities is described, for example, in K. Hanzawa, S. Iimura, H. Hiramatsu, H. Hosono: J. Am. Chem. Soc., Vol. 141, No. 13, pp. 5343-5349 (2019).

Each of the first quantum dots 31 is desirably a core-shell quantum dot. Hence, as illustrated in FIG. 4, each first quantum dot 31 includes a core 61 and a shell 62. The shell 62 is disposed over the surface of the core 61. The shell 62 can inactivate defects found on the surface of the core 61. Such a feature makes it possible to reduce the non-radiative recombination of the holes 51 and the electrons 52 caused by the defects, and the resulting loss of the injected electrons 52.

The first quantum dot 31 desirably includes a ligand. The ligand includes at least one selected from the group consisting of an organic ligand and an inorganic ligand. The ligand adheres to the surface of the shell 62. Thus, the ligand can inactivate defects found on the surface of the shell 62. Moreover, the ligand allows the first quantum dots 31 to disperse more thoroughly in a dispersion medium contained in a coating liquid to be applied for forming the first quantum dot layer 21.

The first quantum dots 31 have a particle size capable of exhibiting a quantum confinement effect, and have a particle size corresponding to a wavelength of the light 53 to be emitted from each light-emitting element 10 and to a material contained in the first quantum dots 31. The particle size is, for example, approximately several namometers to several tens of namometers.

Each of the second quantum dots 32 is desirably a core-shell quantum dot. Hence, as illustrated in FIG. 4, the second quantum dot 32 includes a core 63 and a shell 64. The shell 64 is disposed over the surface of the core 63. The shell 64 can inactivate defects found on the surface of the core 63. Such a feature makes it possible to reduce the non-radiative recombination of the holes 51 and the electrons 52 caused by the defects, and the resulting loss of the injected electrons 52. Thus, the electrons 52 can be confined without loss.

As to the second quantum dot 32, both the core 63 and the shell 64 may be formed of an n-type impurity semiconductor containing a group II-VI compound doped with impurities. Alternatively, the core 63 may be formed of an n-type impurity semiconductor containing a group III-V compound doped with impurities, and the shell 64 may be formed of an n-type impurity semiconductor containing a group II-VI compound doped with impurities.

As to the second quantum dot 32, both the core 63 and the shell 64 may be desirably formed of an n-type impurity semiconductor containing a semiconductor doped with impurities. However, either the core 63 or the shell 64 alone may be formed of an n-type impurity semiconductor containing a semiconductor doped with impurities.

### 2.11 Method for Forming First Quantum Dot Layer and Second Quantum Dot Layer

The first quantum dot layer 21 can be formed at a time through the following steps. A colloidal solution, containing the first quantum dots 31 and a dispersion medium in which the first quantum dots 31 are dispersed, is applied by, for example, spin coating to form a coating film. Then, the coating film is dried to form the first quantum dot layer 21. The first quantum dot layer 21 may be separately formed for each of the light-emitting elements 10R, 10G, and 10B. Patterning in the forming of the first quantum dot layer 21 may be, for example, printing the first quantum dot layer 21 by inkjet printing, or performing photolithography on a coating film including the first quantum dots 31 and a resist in which the first quantum dots 31 are dispersed.

### 2.12 Thicknesses of First Quantum Dot Layer and Second Quantum Dot Layer

The first quantum dot layer 21 has a thickness of desirably 10 nm or more and 50 nm or less. If the thickness is less than 10 nm, it is likely to be difficult to form the first quantum dot layer 21 having a uniform thickness over the entire surface of each light emitting element 10. For this reason, the emission intensity is likely to be non-uniform among the light-emitting elements 10. If the thickness is more than 50 nm, the thickness is likely to be longer than an injection length and a diffusion length of the holes 51. For this reason, the external quantum efficiency is likely to be low among the light-emitting elements 10. The thickness of the first quantum dot layer 21 can be adjusted depending on, for example, the particle size of the first quantum dots 31 and an application condition of the colloidal solution to be applied in forming the first quantum dot layer 21.

The second quantum dot layer 22 has a thickness of desirably 10 nm or more and 50 nm or less. The thickness of the second quantum dot layer 22 can be adjusted depending on, for example, the particle size of the second quantum dots 32 and an application condition of the colloidal solution to be applied in forming the second quantum dot layer 22.

The quantum dot layer 14 has a thickness of desirably 20 nm or more and 100 nm or less.

### 2.13 Materials of First Electrode and Second Electrode

The first electrode 12 and the second electrode 13 are made of a conductive material. The conductive material includes at least one selected from the group consisting of, for example, a metal and an oxide. The metal may be either a pure metal or an alloy. The metal includes at least one selected from the group consisting of, for example, Al, Mg, Li, Ag, Cu, and Au. The oxide includes at least one selected from the group consisting of, for example, indium tin oxide (ITO), indium zinc oxide (IZO), zinc oxide (ZnO), aluminum zinc oxide (AZO), boron zinc oxide (BZO), and indium gallium zinc oxide (IGZO). Each of the first electrode 12 and the second electrode 13 may be a single layer made of one kind of a conductive material, or may be a multilayer stack including two or more layers made of two or more different conductive materials. Two or more layers may include both of metal and oxide layers.

### 2.14 Method for Forming First Electrode and Second Electrode

The first electrode 12 and the second electrode 13 are formed by such a method as vacuum evaporation, sputtering, or coating. If the first electrode 12 and the second electrode 13 are made of a compound material such as ITO, the first electrode 12 and the second electrode 13 are formed desirably by coating. The coating includes: coating with a colloidal solution; and coating with a precursor and firing the precursor. If the first electrode 12 and the second electrode 13 are formed by coating with a colloidal solution, a colloidal solution containing nanoparticles is applied to form a coating film, and the formed coating film is dried. If the first electrode 12 and the second electrode 13 are formed by coating with a precursor and firing the precursor, the precursor is applied to form a coating film, and the formed coating film is fired.

In producing the display device 1, forming the first electrode 12 and the second electrode 13 involves patterning as necessary. The patterning includes photolithography, mask evaporation, and printing by inkjet printing.

### 2.15 Materials of Hole Injection Layer and Hole Transport Layer

The hole injection layer 15 is made of a hole injecting material. The hole injecting material includes at least one selected from the group consisting of, for example, an organic hole injecting material and an inorganic hole injecting material. The organic hole injecting material includes, for example, poly(3,4-ethylenedioxythiophene): poly(-styrenesulfonic acid) (PEDOT: PSS). The inorganic hole injecting material includes at least one selected from the group consisting of, for example, NiO, MgNiO, and Cr₂O₃.

The hole transport layer 16 is made of a hole transporting material. The hole transporting material includes at least one selected from the group consisting of an organic hole transporting material and an inorganic hole transporting material. The organic hole transporting material includes at least one selected from the group consisting of, for example, poly[2,7-(9,9-di-n-octylfluorene)-(1,4-phenylene-((4-sec-butylphenyl)imino)-1,4-phenylene)] (TFB), 2,3,6,7,10,11-hexacyano-0,1,4,5,8,9,12-hexaazatriphenylene (HATCN), poly(N-vinylcarbazole) (PVK), and poly(triphenylamine) derivatives (Poly-TPD). The inorganic hole transporting material includes at least one selected from the group consisting of, for example, NiO, MgNiO, and Cr₂O₃.

As described above, in the display device 1 of the first embodiment, the electrons 52 can be kept from overflowing the first quantum dot layer 21 into the hole injection layer 15 and the hole transport layer 16. Hence, even if the hole injection layer 15 and the hole transport layer 16 are made of an organic material, the hole injection layer 15 and the hole transport layer 16 can be kept from deforming as seen in anodization. However, if the hole injection layer 15 and the hole transport layer 16 are made of an inorganic material having high chemical stability, the hole injection layer 15 and the hole transport layer 16 can be further kept from deforming. As a result, each light-emitting element 10 can improve reliability.

The inorganic material may be an oxide or a non-oxide. Desirably, the inorganic material is an oxide having high chemical stability. The oxide includes, for example, a metal oxide. If the inorganic material forming the hole injection layer 15 and the hole transport layer 16 contains an oxide, oxygen defects are formed in the oxide such that conduction electrons can be generated inside the hole injection layer 15 and the hole transport layer 16. Hence, if the hole injection layer 15 and the hole transport layer 16 are formed by sputtering, concentration of an oxygen gas contained in a gas to be supplied is adjusted so that density of the oxygen defects to be formed falls low.

### 2.16 Method for Forming Hole Injection Layer and Hole Transport Layer

The hole injection layer 15 and the hole transport layer 16 are formed by the same method as the method for forming the first electrode 12 and the second electrode 13. Note that, if the hole transport layer 16 is formed immediately above the quantum dot layer 14, the hole transport layer 16 is formed desirably by either coating with a colloidal solution or coating with a precursor and firing the precursor. In a case where the hole transport layer 16 is formed by either coating with a colloidal solution or coating with a precursor and firing the precursor, compared with a case where the hole transport layer 16 is formed by either vacuum evaporation or sputtering, the former case makes it possible to reduce damage to the quantum dot layer 14 caused by heat or charged particles.

In producing the display device 1, forming the hole injection layer 15 and the hole transport layer 16 involves patterning as necessary. The patterning includes photolithography, mask evaporation, and printing by inkjet printing.

### 2.17 Materials of Electron Transport Layer

The electron transport layer 17 is made of an electron transporting material. The electron transporting material includes, for example, an inorganic electron transporting material. The inorganic electron transporting material includes at least one selected from the group consisting of, for example, ZnO and MgZnO.

### 2.18 Method for Forming Electron Transport Layer

The electron transport layer 17 is formed by the same method as the method for forming the first electrode 12 and the second electrode 13. Note that, if the electron transport layer 17 is formed immediately above the quantum dot layer 14, the electron transport layer 17 is desirably formed by either coating with a colloidal solution or coating with a precursor and firing the precursor. In a case where the electron transport layer 17 is formed by either coating with a colloidal solution or coating with a precursor and firing the precursor, compared with a case where the electron transport layer 17 is formed by either vacuum evaporation or sputtering, the former case makes it possible to reduce damage to the quantum dot layer 14 caused by heat or charged particles.

In producing the display device 1, forming the electron transport layer 17 involves patterning as necessary. The patterning includes photolithography, mask evaporation, and printing by inkjet printing.

### 2.19 Junction between Electron Transport Layer and Electron Accumulating Layer

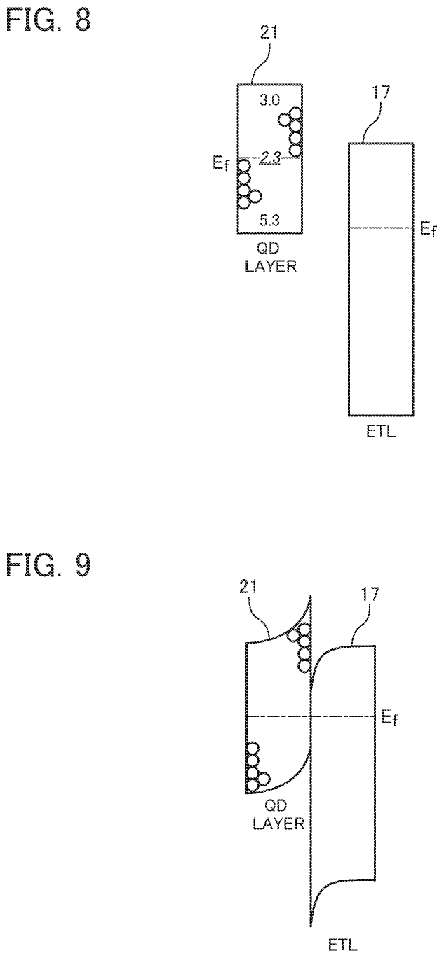

FIGS. 8 and 9 are schematic diagrams illustrating band structures of an electron transport layer (ETL) 17 and a first quantum dot layer (QD layer) 21 included in a display device of a second reference example. FIG. 8 is a schematic diagram illustrating a band structure in which the electron transport layer 17 and the first quantum dot layer 21 are isolated from each other in an isolated state. FIG. 9 illustrates a band structure in which the electron transport layer 17 and the first quantum dot layer 21 join together in a junction state not through the second quantum dot layer 22.

FIGS. 8 and 9 illustrate band gaps of the electron transport layer 17 and the first quantum dot layer 21.

As illustrated in FIG. 8, in the isolated state, the first quantum dot layer 21 has a Fermi level E_{f} near a middle between the CBM and VBM inside the band gap.

As illustrated in FIG. 9, in the junction state, the bands of the electron transport layer 17 and the first quantum dot layer 21 curve, so that the Fermi level E_{f} of the electron transport layer 17 and the Fermi level E_{f} of the first quantum dot layer 21 match. Since the Fermi level E_{f} of the first quantum dot layer 21 is close to the Fermi level E_{f} of the electron transport layer 17, the curves of the bands of the electron transport layer 17 and the first quantum dot layer 21 are small. Hence, the junction between the electron transport layer 17 and the first quantum dot layer 21 serves as an electron barrier that strongly keeps the electrons 52 from moving from the second electrode 13 toward the first electrode 12. Thus, in order to inject the electrons 52 into the first quantum dot layer 21 and to cause each light-emitting element to emit the light 53, a high drive voltage has to be applied between the first electrode 12 and the second electrode 13.

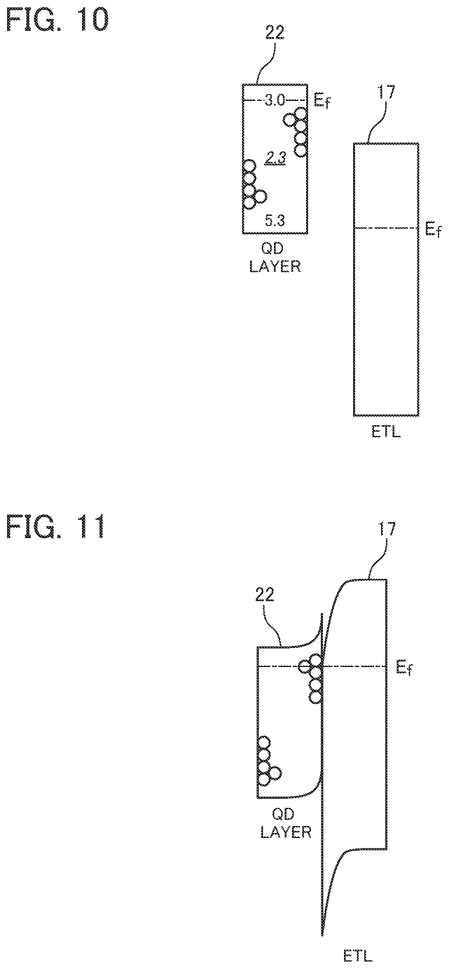

FIGS. 10 and 11 are schematic diagrams illustrating band structures of the electron transport layer (ETL) 17 and the second quantum dot layer (QD layer) 22 included in the display device 1 of the first embodiment. FIG. 10 illustrates a band structure in which the electron transport layer 17 and the first quantum dot layer 22 are isolated from each other in an isolated state. FIG. 11 illustrates a band structure in which the electron transport layer 17 and the second quantum dot layer 22 join together in a junction state.

FIGS. 10 and 11 illustrate band gaps of the electron transport layer 17 and the second quantum dot layer 22.

As illustrated in FIG. 10, in the isolated state, the second quantum dot layer 22 has a Fermi level E_{f} near the CBM inside the band gap.

As illustrated in FIG. 11, in the junction state, the bands of the electron transport layer 17 and the second quantum dot layer 22 curve, so that the Fermi level E_{f} of the electron transport layer 17 and the Fermi level E_{f} of the second quantum dot layer 22 match. Since the Fermi level E_{f} of the second quantum dot layer 22 is far from the Fermi level E_{f} of the electron transport layer 17, the curve of the band of the electron transport layer 17 is large. Hence, the junction between the electron transport layer 17 and the second quantum dot layer 22 does not serve as an electron barrier that strongly keeps the electrons 52 from moving from the second electrode 13 toward the first electrode 12. Thus, in order to inject the electrons 52 into the first quantum dot layer 21 and to cause each light-emitting element 10 to emit the light 53, a high drive voltage does not have to be applied between the first electrode 12 and the second electrode 13.

The electron barrier formed at the junction between the first quantum dot layer 21 and the second quantum dot layer 22 is created by a difference in electron concentration between the first quantum dot layer 21 and the second quantum dot layer 22. Moreover, the drive voltage to be applied between the first electrode 12 and the second electrode 13 is a forward voltage.

Thus, when the electron barrier is formed at the junction between the first quantum dot layer 21 and the second quantum dot layer 22, the drive voltage to be applied between the first electrode 12 and the second electrode 13 rises. The rise of the drive voltage is smaller than the fall of the drive voltage caused by the decrease in the electron barrier formed at the junction between the electron transport layer 17 and the second quantum dot layer 22. Hence, in the display device 1 of the first embodiment, the drive voltage can be decreased.

### 2.20 Junction between Hole Transport Layer and Light-Emitting Layer

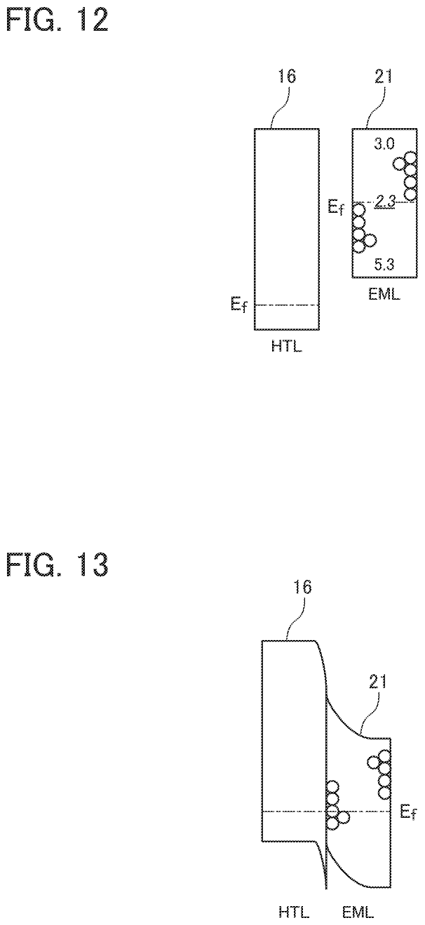

FIGS. 12 and 13 are schematic diagrams illustrating band structures of the hole transport layer (HTL) 16 and the first quantum dot layer 21 serving as a light-emitting layer (EML). The hole transport layer 16 and the first quantum dot layer 21 are included in the display device 1 of the first embodiment. FIG. 12 illustrates a band structure in which the hole transport layer 16 and the first quantum dot layer 21 are isolated from each other in an isolated state. FIG. 13 illustrates a band structure in which the hole transport layer 16 and the first quantum dot layer 21 join together in a junction state.

FIGS. 12 and 13 illustrate band gaps of the hole transport layer 16 and the first quantum dot layer 21.

As illustrated in FIG. 12, in the isolated state, the first quantum dot layer 21 has a Fermi level E_{f} near a middle between the CBM and VBM inside the band gap.

As illustrated in FIG. 13, in the junction state, the Fermi level E_{f} of the hole transport layer 16 and the band of the first quantum dot layer 21 curve, so that the Fermi level E_{f} of the hole transport layer 16 and the Fermi level E_{f} of the first quantum dot layer 21 match. Hence, the junction between the hole transport layer 16 and the first quantum dot layer 21 does not serve as a hole barrier that strongly keeps the holes 51 from moving from the first electrode 12 toward the second electrode 13.

### 2.21 Method for Forming Second Quantum Dot Layer

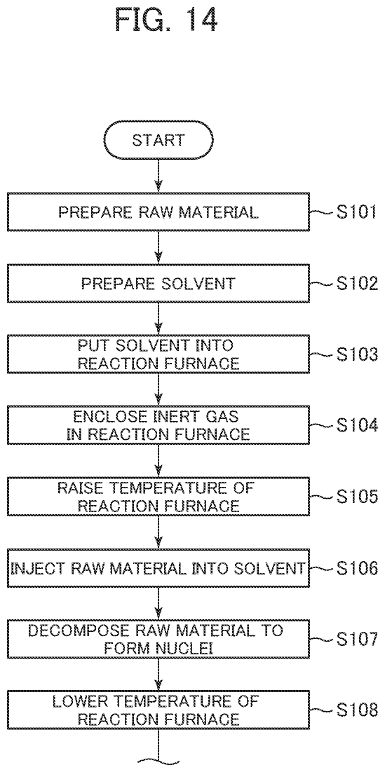

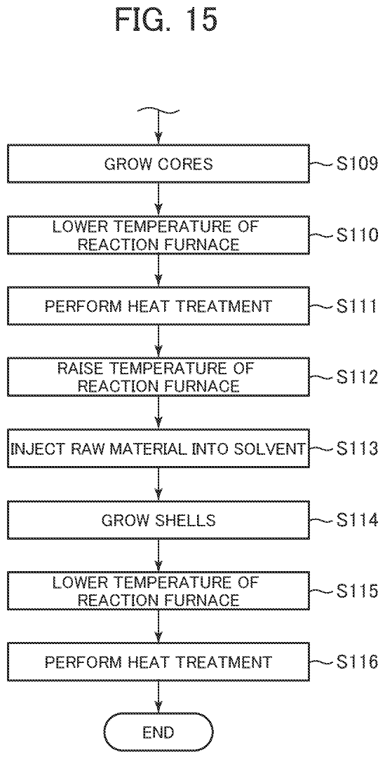

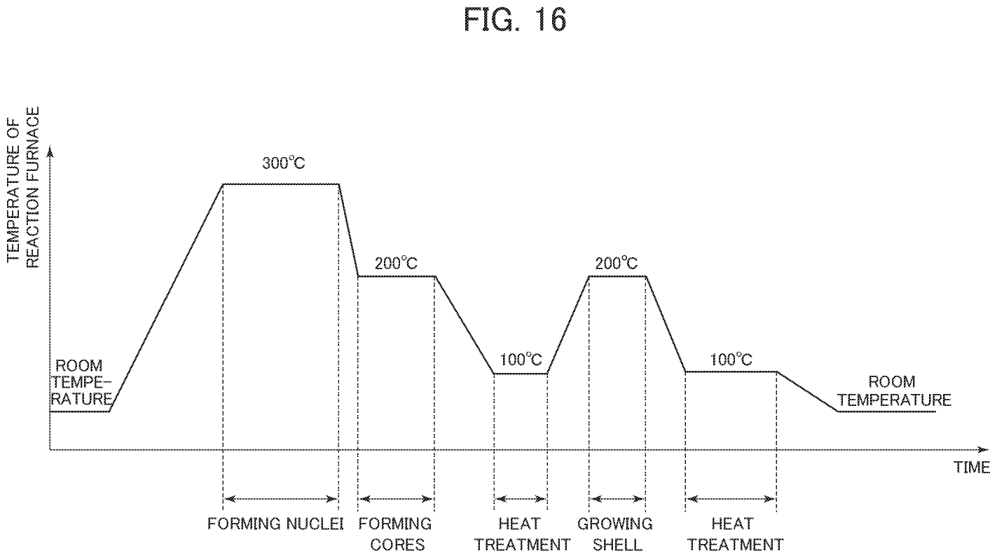

FIGS. 14 and 15 are flowcharts showing a method for producing the second quantum dots 32 included in the display device 1 of the first embodiment. FIG. 16 is a graph showing a profile of temperatures of a reaction furnace in producing the second quantum dots 32 to be included in the display device 1 of the first embodiment.

In producing the second quantum dots 32, Steps S101 to S116 in FIGS. 14 and 15 are carried out.

At Step 101, a raw material is prepared. If the cores 63 are formed of an n-type impurity semiconductor containing CdSe doped with Al, and the shells 64 are formed of an n-type impurity semiconductor containing ZnS doped with Al, the raw material to be prepared is made of, for example, a group II element raw material, a dopant raw material, a group VI element raw material, octylamine, and bis(trimethylsilyl)sulfide. The group II element raw material is made of diethyl Cd for the cores 63 and diethyl Zn for the shells 64. The dopant raw material is made of at least one selected from the group consisting of triethyl Al and trimethyl Al. The VI element raw material is made of powdered Se for the cores 63 and powdered S for the shells 64. The group II element raw material, the dopant element raw material, the group VI element raw material, octylamine and bis(trimethylsilyl)sulfide are weighed so that the molar ratio of the group II element to the dopant element to the IV element to octylamine to bis(trimethylsilyl)sulfide is 10:0.01:9:7:3.

At subsequent Step S102, a solvent is prepared. The prepared solvent is made of, for example, trioctylphosphine oxide and hexadecylamine. Trioctylphosphine oxide and hexadecylamine are weighed so that the weight ratio of trioctylphosphine oxide to hexadecylamine is 2:1.

At subsequent Step 103, the prepared solvent is put into a reaction furnace.

At subsequent Step 104, an inert gas is enclosed in the reaction furnace. The inert gas to be enclosed is, for example, an Ar gas.

At subsequent Step 105, the temperature of the reaction furnace is raised. As shown in FIG. 16, the temperature of the reaction furnace is raised to, for example, 300° C. Thus, the put solvent is liquefied.

At subsequent Step 106, the prepared raw material is injected into the liquefied solvent. The raw material is injected into the solvent by, for example, a high-pressure injector.

At subsequent Step 107, the injected raw material is decomposed to form nuclei.

At subsequent Step 108, the temperature of the reaction furnace is lowered. As shown in FIG. 16, the temperature of the reaction furnace is lowered to 200° C. at a temperature decrease rate of, for example, 400° C./min.

At subsequent Step 109, the cores 63 grow. The cores 63 grow at a particle-size growth rate of, for example, 10 nm/200 minutes. As a result, diethyl Cd is consumed.

At subsequent Step 110, the temperature of the reaction furnace is lowered. As shown in FIG. 16, the temperature of the reaction furnace is decreased to 100° C. at a temperature decrease rate of, for example, 30° C./sec.

At subsequent Step 111, a heat treatment is performed. The heat treatment is carried out for, for example, one hour.

At subsequent Step 112, the temperature of the reaction furnace is raised. As shown in FIG. 16, the temperature of the reaction furnace is raised to, for example, 200° C.

At a subsequent Step 113, a raw material of the shells is injected into a solvent. The raw material to be injected is, for example, diethyl Zn.

At subsequent Step 114, the shells 64 grow. The shells 64 grow at a particle-size growth rate of, for example, 10 nm/200 minutes.

At subsequent Step 115, the temperature of the reaction furnace is lowered. As shown in FIG. 16, the temperature of the reaction furnace is decreased to 100° C. at a temperature decrease rate of, for example, 30° C./sec.

At subsequent Step 116, a heat treatment is performed. The heat treatment is carried out for, for example, one hour.

### 3 Second Embodiment

Described below is how a second embodiment is different from the first embodiment. As to omitted points, the features employed in the first embodiment are also employed in the second embodiment.

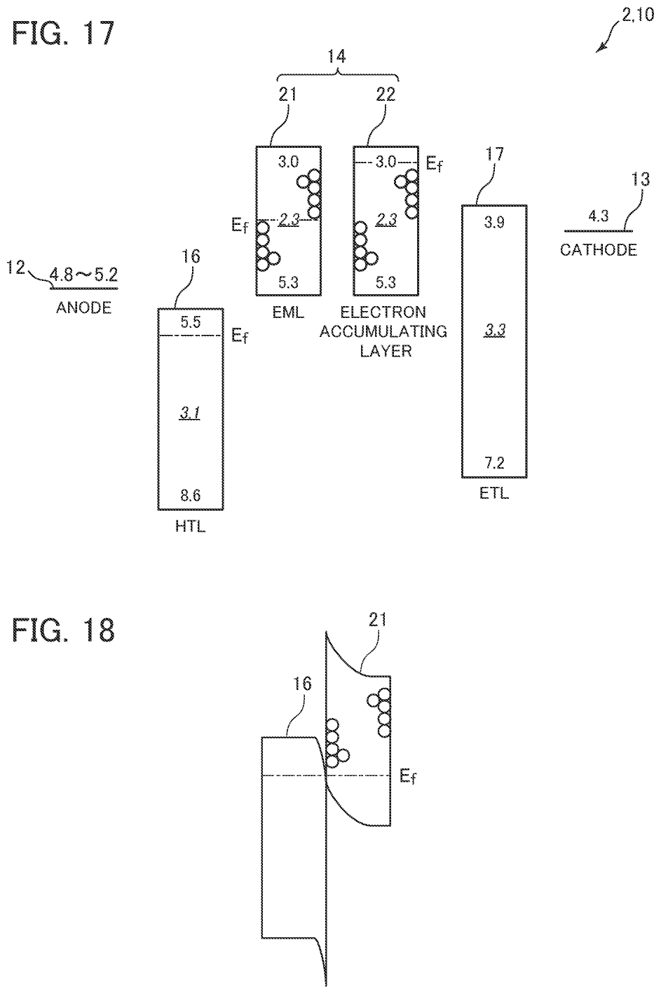

FIG. 17 is a schematic diagram illustrating a band structure of the first electrode 12, the second electrode 13, the hole transport layer (HTL) 16, the electron transport layer (ETL) 17, the first quantum dot layer 21 serving as a light-emitting layer (EML), and the second quantum dot layer 22 serving as an electron accumulating layer, all of which are included in a display device 2 of the second embodiment. FIG. 17 illustrates a band structure in which the first electrode 12, the second electrode 13, the hole transport layer 16, the electron transport layer 17, the first quantum dot layer 21, and the second quantum dot layer 22 are isolated from one another in an isolated state.

FIG. 18 is a schematic diagram illustrating a band structure of the hole transport layer 16 and the first quantum dot layer 21 included in the display device 2 of the second embodiment. FIG. 18 illustrates a band structure in which the hole transport layer 16 and the first quantum dot layer 21 join together in a junction state.

As illustrated in FIGS. 17 and 18, in the display device 2 of the second embodiment, the hole transport layer 16 has a very deep CBM. Hence, the hole transport layer 16 has the CBM near the VBM of the first quantum dot layer 21.

Moreover, in the display device 2 of the second embodiment, the hole transport layer 16 has an n-type conductivity. For this reason, as illustrated in FIG. 17, the hole transport layer 16 has a Fermi level E_{f} near the CBM of the hole transport layer 16. Hence, the hole transport layer 16 has the Fermi level E_{f} near the VBM of the first quantum dot layer 21.

Thus, the electrons 52 can be extracted from the VBM of the first quantum dot layer 21 to the CBM of the hole transport layer 16. This is equivalent to a case where the holes 51 can be injected from the CBM of the hole transport layer 16 into the VBM of the first quantum dot layer 21.

The hole transport layer 16 having the very deep CBM and the n-type conductivity can be formed of an inorganic material containing an oxide including at least one selected from the group consisting of Mo, W, V, and Re.

Such a hole transport layer 16 can improve injection of the holes 51 from the hole transport layer 16 into the first quantum dot layer 21. As a result, each light-emitting element 10 can improve reliability.

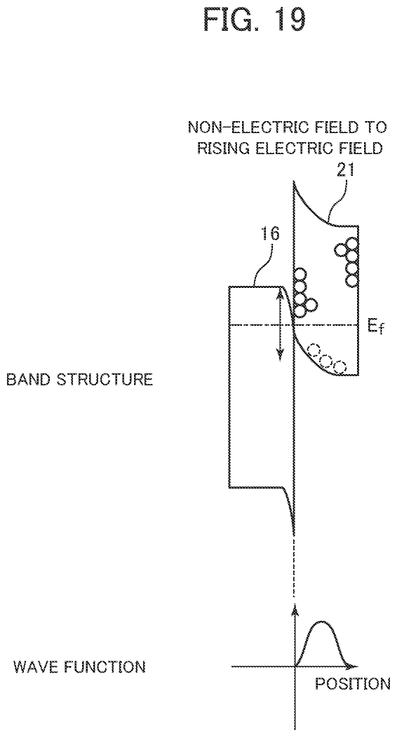

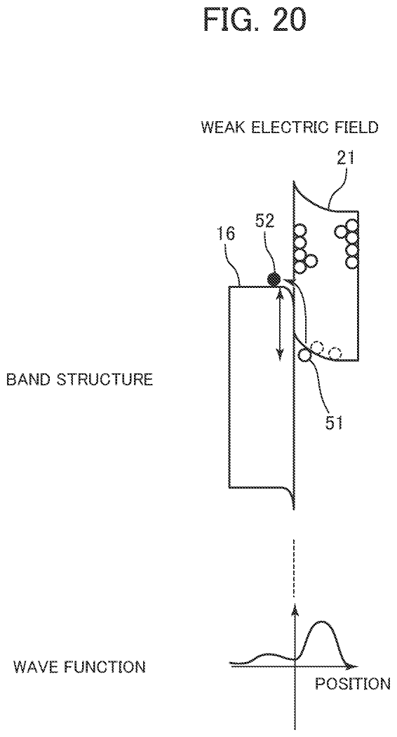

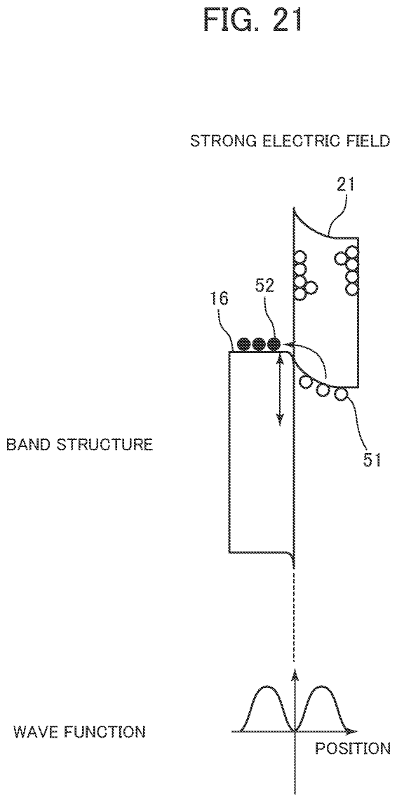

FIGS. 19, 20, and 21 illustrate band structures of the hole transport layer 16 and the first quantum dot layer 21 included in the display device 2 of the second embodiment, and schematic waveforms representing wave functions of the electrons 52 in the hole transport layer 16 and the first quantum dot layer 21. FIG. 19 illustrates a band structure and a schematic waveform observed when an external electric field to be applied to the hole transport layer 16 and the first quantum dot layer 21 is either a non-electric field, or a rising electric field or less. FIG. 20 illustrates a band structure and a schematic waveform observed when the external electric field is stronger than the rising electric field, but is a weak electric field. FIG. 21 illustrates a band structure and a schematic waveform observed when the external electric field is stronger than the rising electric field, and is a strong electric field.

When a drive voltage is applied between the first electrode 12 and the second electrode 13, and an external electric field is applied to the hole transport layer 16 and the first quantum dot layer 21, the Fermi levels E_{f} of the hole transport layer 16 and the first quantum dot layer 21 are inclined downwards from the second electrode 13 toward the first electrode 12. Hence, the CBM of the hole transport layer 16 and the VBM of the first quantum dot layer 21 come close to each other. As a result, the band structure of the hole transport layer 16 and the first quantum dot layer 21 changes from the band structure illustrated in FIG. 19 through the band structure illustrated in FIG. 20 to the band structure illustrated in FIG. 21.

As illustrated in FIG. 19, if the external electric field to be applied to the hole transport layer 16 and the first quantum dot layer 21 is either a non-electric field, or a rising electric field or less, the CBM of the hole transport layer 16 and the VBM of the first quantum dot layer 21 are far apart from each other. Hence, the wave function of the electrons 52 in the VBM of the first quantum dot layer 21 takes on a large value; whereas, the wave function of the electrons 52 in the CBM of the hole transport layer 16 takes on a small value. Thus, the electrons 52 are unlikely to be extracted from the VBM of the first quantum dot layer 21 to the CBM of the hole transport layer 16. As a result, the VBM of the first quantum dot layer 21 is occupied with the electrons 52. Moreover, the holes 51 are not generated in the VBM of the first quantum dot layer 21.

The fact that the VBM of the first quantum dot layer 21 is occupied with the electrons 52 does not exclude a case where that the holes 51 and the electrons 52 that exhibit intrinsic carrier density are found in the VBM of the first quantum dot layer 21. Note that the intrinsic carrier density is proportional to exp(−Eg) where the band gap is Eg. If the first quantum dot layer 21 includes a semiconductor with a wide band gap, the intrinsic carrier density is low.

As illustrated in FIG. 20, if the external electric field to be applied to the hole transport layer 16 and the first quantum dot layer 21 is a weak electric field, the CBM of the hole transport layer 16 and the VBM of the first quantum dot layer 21 start to come close to each other. Hence, a resonance starts to occur between the wave function of the electrons 52 in the VBM of the first quantum dot layer 21 and the wave function of the electrons 52 in the CBM of the hole transport layer 16. Thus, the wave function of the electrons 52 in the CBM of the hole transport layer 16 starts to take on a value having a certain magnitude. As a result, the extraction of the electrons 52 from the VBM of the first quantum dot layer 21 to the CBM of the hole transport layer 16 starts by resonant tunneling. When the electrons 52 are extracted from the VBM of the first quantum dot layer 21 occupied with the electrons 52, the holes 51 start to form in the VBM of the first quantum dot layer 21. This phenomenon is equivalent to injection of the holes 51 from the hole transport layer 16 into the first quantum dot layer 21. The holes 51 injected from the hole transport layer 16 into the first quantum dot layer 21 and the electrons 52 injected from the second quantum dot layer 22 into the first quantum dot layer 21 radiatively recombine. Thus, the first quantum dot layer 21 starts to emit the light 53.

As illustrated in FIG. 21, when each light-emitting element 10 is driven normally and the external electric field applied to the hole transport layer 16 and the first quantum dot layer 21 becomes a strong electric field, the CBM of the hole transport layer 16 and the VBM of the first quantum dot layer 21 come closer to each other. Accordingly, more electrons 52 are extracted from the VBM of the first quantum dot layer 21 to the CBM of the hole transport layer 16. Hence, more holes 51 are injected from the hole transport layer 16 into the first quantum dot layer 21. Thus, the radiative recombination between the hole 51 and the electron 52 increases. As a result, more light 53 is emitted from the first quantum dot layer 21.

If the quantum dot layer 14 includes the first quantum dot layer 21 containing an intrinsic semiconductor but does not include the second quantum dot layer 22 containing an n-type impurity semiconductor, a high electron barrier is formed between the electron transport layer 17 and the quantum dot layer 14. This high electron barrier restricts reinforcement of the external electric field to be applied to the hole transport layer 16 and the quantum dot layer 14. The restriction causes saturation of an increase, in the luminance of each light emitting element 10, observed when the drive voltage to be applied between the first electrode 12 and the second electrode 13 is increased.

However, the quantum dot layer 14 includes the first quantum dot layer 21 and the second quantum dot layer 22. Such a feature successfully weakens the external electric field that has to be applied to the quantum dot layer 14, the hole transport layer 16, and the electron transport layer 17 in order to inject the electrons 52 from the electron transport layer 17 into the quantum dot layer 14. The weakened external electric field allows reduction of the drive voltage to be applied between the first electrode 12 and the second electrode 13 in order to inject the electrons 52 from the electron transport layer 17 into the quantum dot layer 14. In addition, the feature makes it possible to apply a strong external electric field to the junction between the hole transport layer 16 and the first quantum dot layer 21, successfully reducing the saturation of the increase in the luminance of each light emitting element 10.

### 4 Third Embodiment

Described below is how a third embodiment is different from the first embodiment. As to omitted points, features similar to the features employed in the first embodiment are also employed in the third embodiment. Features similar to the features employed in the second embodiment are also employed in the third embodiment.

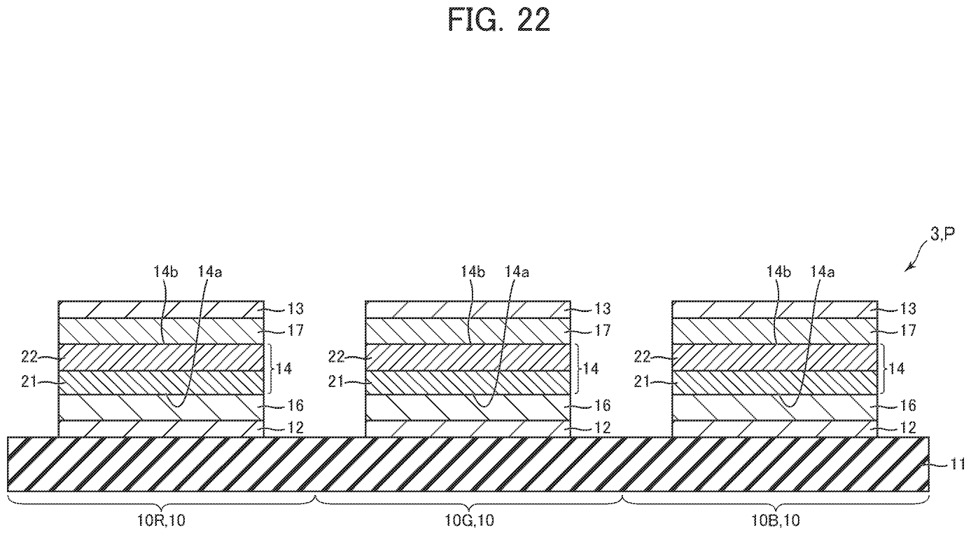

FIG. 22 schematically illustrates cross-sectional views of pixels P included in a display device 3 of the third embodiment.

In the display device 3 of the third embodiment, the first quantum dots 31 included in the first quantum dot layer 21 are impurity quantum dots. Moreover, the second quantum dots 32 included in the second quantum dot layer 22 are intrinsic quantum dots. The impurity quantum dots are p-type impurity quantum dots. The intrinsic quantum dots, not including dopant impurities, contain an intrinsic material not doped with impurities. The impurity quantum dots include dopant impurities, and contain an impurity material doped with impurities. The impurity material is a p-type impurity material.

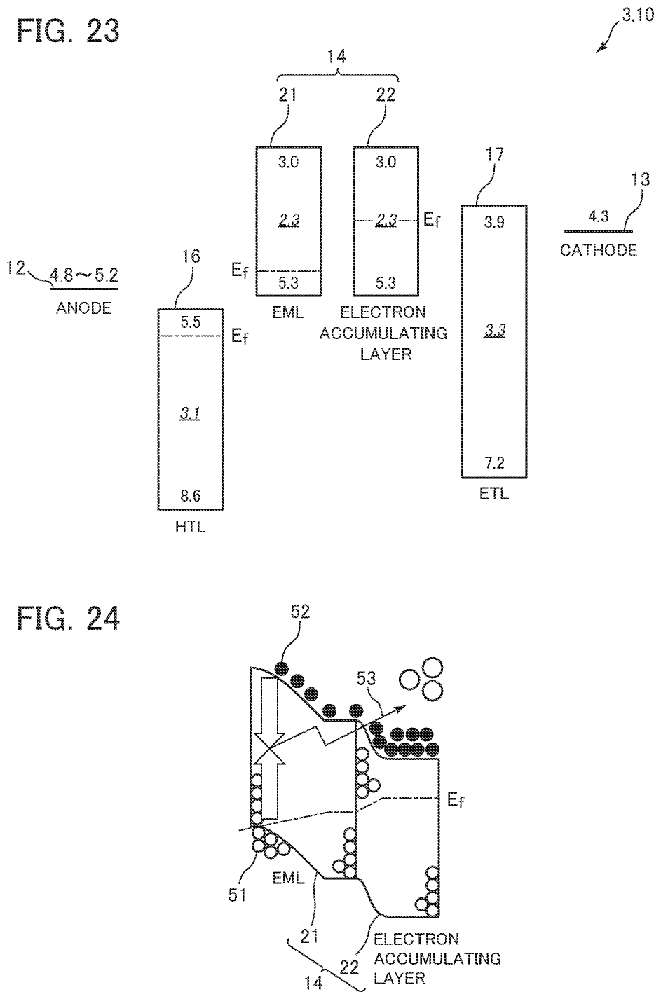

FIG. 23 is a schematic diagram illustrating a band structure of the first electrode 12, the second electrode 13, the hole transport layer (HTL) 16, the electron transport layer (ETL) 17, the first quantum dot layer 21 serving as a light-emitting layer (EML), and the second quantum dot layer 22 serving as an electron accumulating layer, all of which are included in the display device 3 of the third embodiment. FIG. 23 illustrates a band structure in which the first electrode 12, the second electrode 13, the hole transport layer 16, the electron transport layer 17, the first quantum dot layer 21, and the second quantum dot layer 22 are isolated from one another in an isolated state.

FIG. 23 illustrates levels of the first electrode 12 and the second electrode 13, and band gaps of the hole transport layer 16, the electron transport layer 17, the first quantum dot layer 21, and the second quantum dot layer 22.

As illustrated in FIG. 23, in the isolated state, the first quantum dot layer 21, which contains a p-type impurity semiconductor, has a Fermi level E_{f} near the VBM inside the band gap.

The second quantum dot layer 22, which contains an intrinsic semiconductor, has a Fermi level E_{f} near a middle between the CBM and VBM inside the band gap.

FIG. 24 is a schematic diagram illustrating a band structure of the first quantum dot layer 21 and the second quantum dot layer 22 included in the display device 3 of the third embodiment. FIG. 24 illustrates a band structure in a junction/light-emission state in which the first quantum dot layer 21 and the second quantum dot layer 22 join together and the first quantum dot layer 21 emits the light 53.

FIG. 24 illustrates the band gaps of the first quantum dot layer 21 and the second quantum dot layer 22. Moreover, FIG. 24 illustrates the holes 51, the electrons 52, and the light 53.

As illustrated in FIG. 24, in the junction/light-emission state, the bands of the first quantum dot layer 21 and the second quantum dot layer 22 curve, so that the Fermi level E_{f} of the first quantum dot layer 21 and the Fermi level E_{f} of the second quantum dot layer 22 match. Hence, the second quantum dot layer 22 has a CBM deeper than the CBMs of the adjacent first quantum dot layer 21 and electron transport layer 17. Hence, a deep potential is formed in the second quantum dot layer 22 to accumulate the electrons 52.

Thus, the second quantum dot layer 22 serves as an electron accumulating layer that effectively accumulates the electrons 52.

When the first quantum dot layer 21 and the second quantum dot layer 22 join, the junction serves as an electron barrier that keeps the electrons 52 from moving from the second electrode 13 toward the first electrode 12. Hence, the second quantum dot layer 22 can effectively confine the electrons 52 injected from the electron transport layer 17.

Moreover, when the first quantum dot layer 21 and the second quantum dot layer 22 join, the junction serves as a hole barrier that keeps the holes 51 from moving from the first electrode 12 toward the second electrode 13. Hence, the first quantum dot layer 21 can effectively confine the holes 51 injected from the hole transport layer 16.

In the display device 3 of the third embodiment, a deep potential and an electron barrier are formed between the second electrode 13 and the plurality of first quantum dots 31 emitting the light 53. The deep potential accumulates the electrons 52, and the electron barrier keeps the electrons 52 from moving from the second electrode 13 toward the first electrode 12. Such a feature makes it possible to reduce the injection of the electrons 52 into the first quantum dots 31 emitting the light 53. Hence, electron-hole balance can be improved between the hole 51 and the electrons 52 to be injected into the plurality of first quantum dots 31 emitting the light 53. Thus, the holes 51 and the electron 52 can be kept from non-radiatively recombining, and the electron 52 can be less likely to be lost. As a result, each of the light-emitting elements 10 can improve light emission efficiency.

The second quantum dots 32 included in the second quantum dot layer 22 contain a p-type impurity semiconductor. The p-type impurity semiconductor is formed of a semiconductor of the same type as the semiconductor included in the first quantum dots 31. The semiconductor is doped with impurities.

The semiconductor includes at least one selected from the group consisting of, for example, a group II-VI compound, a group III-V compound, a chalcogenide, and a perovskite compound.

The impurities doped into the group II-VI compound includes at least one selected from the group consisting of, for example, a group VA (15) element, Ag, and Cu.

The impurities doped into the group III-V compound includes at least one selected from the group consisting of, for example, a group IIA (2) element and a group IIB (12) element.

The impurities doped into the chalcogenide include, for example, a VB (5) group element. The VB (5) group element includes, for example, Nb.

The impurities doped into the perovskite compound includes at least one selected from the group consisting of, for example, a group IIIA (13) element and P. Doping a perovskite compound with impurities is described, for example, in K. Hanzawa, S. Iimura, H. Hiramatsu, H. Hosono: J. Am. Chem. Soc., Vol. 141, No. 13, pp. 5343-5349 (2019).

The present disclosure shall not be limited to the above embodiments, and may be replaced with configurations that are substantially the same as, that have the same advantageous effects as those of, and that achieve the same object as that of, the configurations described in the above embodiments.

1. A light-emitting element, comprising:
a first electrode;
a second electrode; and
a quantum dot layer disposed between the first electrode and the second electrode,
wherein the quantum dot layer includes:
a first quantum dot that is either an intrinsic quantum dot or an impurity quantum dot; and
a second quantum dot disposed between the second electrode and the first quantum dot, the second quantum dot being either the intrinsic quantum dot or the impurity quantum dot other than the first quantum dot.

2. The light-emitting element according to claim 1,
wherein the first electrode is an anode,
the second electrode is a cathode,
the impurity quantum dot is an n-type impurity quantum dot,
the first quantum dot is the intrinsic quantum dot, and
the second quantum dot is the n-type impurity quantum dot.

3. The light-emitting element according to claim 2,
wherein the n-type impurity quantum dot contains a semiconductor formed of a group II-VI compound doped with at least one selected from the group consisting of a group III element and Mn.

4. The light-emitting element according to claim 2,
wherein the n-type impurity quantum dot contains a semiconductor formed of a group III-V compound doped with a group IV element.

5. The light-emitting element according to claim 2,
wherein the n-type impurity quantum dot contains a semiconductor formed of a chalcogenide doped with halogen.

6. The light-emitting element according to claim 2,
wherein the n-type impurity quantum dot contains a semiconductor formed of a perovskite compound doped with at least one selected from the group consisting of a group V element and La.

7. The light-emitting element according to claim 1,
wherein the first electrode is an anode,
the second electrode is a cathode,
the impurity quantum dot is a p-type impurity quantum dot,
the first quantum dot is the p-type impurity quantum dot, and
the second quantum dot is the intrinsic quantum dot.

8. The light-emitting element according to claim 1,
wherein the quantum dot layer includes: a plurality of first quantum dots that are either a plurality of intrinsic quantum dots or a plurality of impurity quantum dots; and a plurality of second quantum dots that are either the plurality of intrinsic quantum dots or the plurality of impurity quantum dots other than the plurality of first quantum dots, the quantum dot layer having: a first end portion toward the first electrode and a second end portion toward the second electrode, and
the plurality of first quantum dots and the plurality of second quantum dots are disposed such that, at the first end portion, a rate of a number of quantum dots that belong to the plurality of first quantum dots to a sum of the number of the quantum dots that belong to the plurality of first quantum dots and a number of quantum dots that belong to the plurality of second quantum dots is a highest rate, and, at the second end portion, a rate of a number of quantum dots that belong to the plurality of second quantum dots to the sum of a number of quantum dots that belong to the plurality of first quantum dots and the number of the quantum dots that belong to the plurality of second quantum dots is a highest rate.

9. The light-emitting element according to claim 1,
wherein the quantum dot layer includes:
a first quantum dot layer including a plurality of first quantum dots that are either a plurality of intrinsic quantum dots or a plurality of impurity quantum dots; and
a second quantum dot layer disposed between the second electrode and the first quantum dot layer, and including a plurality of second quantum dots that are either the plurality of intrinsic quantum dots or the plurality of impurity quantum dots other than the plurality of first quantum dots.

10. The light-emitting element according to claim 9,
wherein each of the first quantum dot layer and the second quantum dot layer has a thickness of 10 nm or more and 50 nm or less.

11. The light-emitting element according to claim 1,
wherein the quantum dot layer has a thickness of 20 nm or more and 100 nm or less.

12. The light-emitting element according to claim 1,
wherein the first quantum dot allows injected holes and electrons to recombine, and emits light.

13. The light-emitting element according to claim 1,
wherein the second quantum dot is a core-shell quantum dot.

14. The light-emitting element according to claim 1,
wherein the first electrode is an anode,
a hole transport layer is disposed between the anode and the quantum dot layer, the hole transport layer containing a first inorganic material.

15. The light-emitting element according to claim 14,
wherein the first inorganic material contains an oxide including at least one selected from the group consisting of Mo, W, V, and Re.

16. The light-emitting element according to claim 14,
wherein the first electrode is an anode,
a hole injection layer is disposed between the anode and the hole transport layer, the hole injection layer containing a second inorganic material.
